(19) United States
(12) Patent Application Publication
(10) Pub. No.: US 2026/0101515 A1
(43) Pub. Date: Apr. 9, 2026

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventors: Seok Min CHOI, Icheon-si Gyeonggi-do (KR); Jung Shik JANG, Icheon-si Gyeonggi-do (KR); Rho Gyu KWAK, Icheon-si Gyeonggi-do (KR); Mi Seong PARK, Icheon-si Gyeonggi-do (KR); In Su PARK, Icheon-si Gyeonggi-do (KR); Na Yeong YANG, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 19/033,750

(22) Filed: Jan. 22, 2025

(30) Foreign Application Priority Data
Oct. 8, 2024 (KR) 10-2024-0136361

(51) Int. Cl. H10B 43/35; H01L 23/00; H01L 25/065; H01L 25/18; H10B 41/27; H10B 41/35; H10B 43/27; H10B 80/00

(52) U.S. Cl. CPC H10B 43/35; H10B 41/27; H10B 41/35; H10B 43/27; H10B 80/00; H10W 90/00; H10W 90/792

(57) ABSTRACT

A semiconductor device includes: a gate structure including stacked local lines; first contact plugs extending through the gate structure and connected to the local lines, respectively; channel patterns located over the gate structure and connected to the first contact plugs, respectively; a back gate line located between the gate structure and the channel patterns; a block word line located over the channel patterns; and a second contact plug electrically connected to the back gate line.

### CROSS-REFERENCE TO RELATED APPLICATION

The present application claims priority under 35 U.S. C. § 119(a) to Korean Patent Application No. 10-2024-0136361 filed on Oct. 8, 2024, in the Korean Intellectual Property Office, which application is incorporated herein by reference in its entirety.

### BACKGROUND

### 1. Technical Field Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including stacked local lines; first contact plugs extending through the gate structure and connected to the local lines, respectively; channel patterns located over the gate structure and connected to the first contact plugs, respectively; a back gate line located between the gate structure and the channel patterns; a block word line located over the channel patterns; and a second contact plug electrically connected to the back gate line.

In an embodiment, a semiconductor device may include: a gate structure including stacked local lines, the local lines including pads defined by a staircase structure; channel patterns located over the pads, respectively; a block word line located over the channel patterns and extending along a profile of the staircase structure; a back gate line located between the gate structure and the channel patterns and extending along the profile of the staircase structure; first contact plugs penetrating through the channel patterns and connecting the channel patterns and the local lines to each other, respectively; and a second contact plug connected to the back gate line.

In an embodiment, a manufacturing method of a semiconductor device may include: forming a gate structure including conductive layers and insulating layers that are alternately stacked; forming first contact plugs extending through the gate structure and respectively connected to the conductive layers; forming a back gate line over the gate structure; forming channel patterns over the back gate line, the channel patterns being connected to the first contact plugs, respectively; forming a block word line over the channel patterns; and forming a second contact plug connected to the back gate line.

In an embodiment, a manufacturing method of a semiconductor device may include: forming a stack including first material layers and second material layers that are alternately stacked; forming a staircase structure in the stack, the staircase structure defining pads of the first material layers; forming a back gate line along a profile of the staircase structure; forming channel patterns over the back gate line, the channel patterns being located to correspond to the pads; forming a block word line over the channel patterns, the block word line extending along the profile of the staircase structure; forming first contact plugs penetrating through the channel patterns and connecting the channel patterns and the first material layers to each other, respectively; and forming a second contact plug connected to the back gate line.

### BRIEF DESCRIPTION OF THE DRAWINGS

FIG. 1 is a block diagram illustrating the configuration of a semiconductor device in accordance with an embodiment.

FIG. 2 is a block diagram illustrating the configuration of a semiconductor device in accordance with an embodiment.

FIGS. 3A and 3B are diagrams illustrating the structure of a semiconductor device in accordance with an embodiment.

FIGS. 4A, 4B, and 4C are diagrams illustrating the structure of a semiconductor device in accordance with an embodiment.

FIGS. 5A, 5B, 5C, and 5D are diagrams illustrating the structure of a semiconductor device in accordance with an embodiment.

FIG. 6 is a diagram illustrating the structure of a semiconductor device in accordance with an embodiment.

FIGS. 7A, 7B, 7C, 7D, 7E, 7F, 7G, 7H, and 7I are diagrams for describing a manufacturing method of a semiconductor device in accordance with an embodiment.

FIGS. 8A, 8B, and 8C are diagrams for describing a manufacturing method of a semiconductor device in accordance with an embodiment.

FIG. 9 is a configuration diagram of a semiconductor device in accordance with an embodiment.

FIG. 10 is a configuration diagram of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, in an embodiment, it is possible to improve the degree of integration of a semiconductor device. In an embodiment, it is also possible to provide a semiconductor device having a stable structure and improved reliability.

Hereafter, embodiments in accordance with the technical spirit of the present disclosure will be described with reference to the accompanying drawings.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

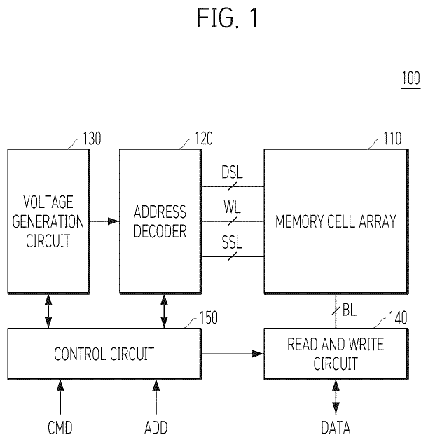

FIG. 1 is a block diagram illustrating the configuration of a semiconductor device in accordance with an embodiment.

Referring to FIG. 1, the semiconductor device 100 may include a memory cell array 110, an address decoder 120, a voltage generation circuit 130, a read and write circuit 140, and a control circuit 150.

The memory cell array 110 may include memory cells. As an example, the memory cell array 110 may include memory blocks, each of which may include pages. Here, the memory block may be a unit of an erase operation, and the page may be a unit of a read operation. The memory cell array 110 may be connected to the address decoder 120 through row lines such as a source select line SSL, a word line WL, and a drain select line DSL The memory cell array 110 may be connected to the read and write circuit 140 through a column line such as a bit line BL.

The control circuit 150 may receive a command CMD and an address ADD from a controller. The control circuit 150 may generate control signals to perform internal operations such as a program operation, a read operation, and an erase operation according to the received command CMD. The control circuit 150 may output the control signals to the voltage generation circuit 130, the address decoder 120, and the read and write circuit 140.

The voltage generation circuit 130 may generate internal voltages of various voltage levels for performing the internal operations, and may provide the generated internal voltages to the address decoder 120. The internal voltage may be an operation voltage for performing the program operation, the read operation, the erase operation, or the like. As an example, the internal voltage may be a body bias voltage supplied to a back gate line in order to control a body bias of a pass transistor.

As an example, the voltage generation circuit 130 may generate a program voltage, a pass voltage, a body bias voltage, a bit line voltage, or the like, for performing the program operation. The voltage generation circuit 130 may generate a read voltage, a pass voltage, a body bias voltage, a bit line voltage, or the like, for performing the read operation. The read operation may be a verify operation for verifying the program operation or the erase operation. The voltage generation circuit 130 may generate an erase voltage, a gate induced drain leakage (GIDL) voltage, a body bias voltage, or the like, for performing the erase operation.

The address decoder 120 may activate the source select line SSL, the word line WL, or the drain select line DSL according to the address. The address decoder 120 may transmit a voltage level of a global line to a local line.

The read and write circuit 140 may be connected to the memory cell array 110 through the bit lines BL. During the program operation, the read and write circuit 140 may operate as a writer driver and may input data DATA that is to be stored in the memory cell array 110. During the read or verify operation, the read and write circuit 140 may operate as a sense amplifier and may output data stored in the memory cell array 110.

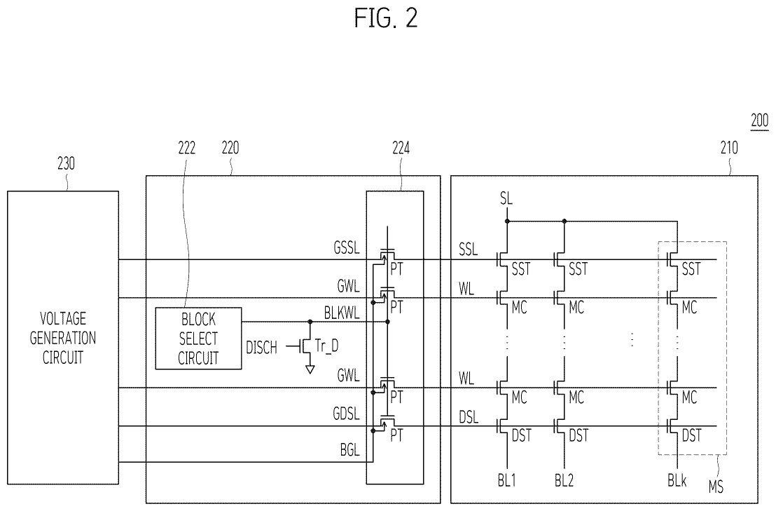

FIG. 2 is a block diagram illustrating the configuration of a semiconductor device in accordance with an embodiment. Hereinafter, the content overlapping with the previously described content may be omitted.

Referring to FIG. 2, the semiconductor device 200 may include a memory cell array 210, an address decoder 220, and a voltage generation circuit 230.

The memory cell array 210 may include a plurality of memory blocks, each of which may include memory strings MS. The memory strings MS may be connected between bit lines BL1 to BLk and a source line SL. Here, k may be an integer of 2 or more. Each memory string MS may include at least one drain select transistor DST, a plurality of memory cells MC, and at least one source select transistor SST.

Gate electrodes of the memory cells MC may be connected to word lines WL. A source select line SSL may be connected to a gate electrode of the source select transistor SST. A connection between the memory string MS and the source line SL may be controlled by the source select line SSL. When the source select transistor SST is turned on, the memory string MS and the source line SL may be connected to each other. A drain select line DSL may be connected to a gate electrode of the drain select transistor DST. A connection between the memory string MS and the bit lines BL1 to BLk may be controlled by the drain select line DSL. When the drain select transistor DST is turned on, the memory string MS and the bit line BL may be connected to each other.

The voltage generation circuit 230 may generate operation voltages required for program operations, read operations, and erase operations of the memory cells. As an example, during the program operation, the voltage generation circuit 230 may transmit a program voltage or a pass voltage to a global word line GWL and transmit a body bias voltage to a back gate line BGL. During the read operation, the voltage generation circuit 230 may transmit a read voltage or a pass voltage to the global word line GWL and transmit a body bias voltage to the back gate line BGL. During the erase operation, the voltage generation circuit 230 may transmit an erase voltage to at least one of a global drain select line GDSL and a global source select line GSSL, transmit a ground voltage to the global word line GWL, and transmit a body bias voltage to the back gate line BGL.

The address decoder 220 may include a block select circuit 222 and a pass circuit 224. The pass circuit 224 may include pass transistors PT for controlling connections between global lines and local lines. The pass transistor PT may control a connection between the global source select line GSSL and the source select line SSL. The pass transistor PT may control a connection between the global word line GWL and the word line WL. The pass transistor PT may control a connection between the global drain select line GDSL and the drain select line DSL.

The block select circuit 222 may generate a block select signal in response to an address, and may transmit the block select signal to the pass circuit 224 through a block word line BLKWL. A discharge transistor Tr_D may discharge the block word line BLKWL in response to a discharge signal DISCH.

The pass circuit 224 may be controlled by the block select signal. The block select signal may be applied to a gate electrode of the pass transistor PT through the block word line BLKWL. When the pass transistor PT is turned on, the global line and the local line may be electrically connected to each other. In this case, a body bias of the pass transistor PT may be controlled by the body bias voltage applied through the back gate line BGL.

According to an embodiment of the configuration described above, turn-on/off operations of the pass transistor PT may be improved and a leakage current and a breakdown voltage of the pass transistor PT may be improved, by the body bias voltage applied to the back gate line BGL.

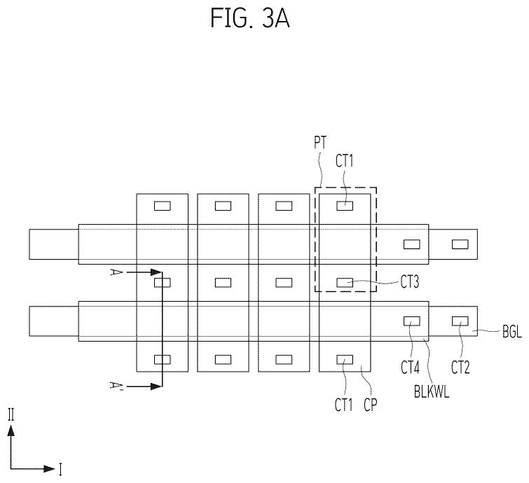

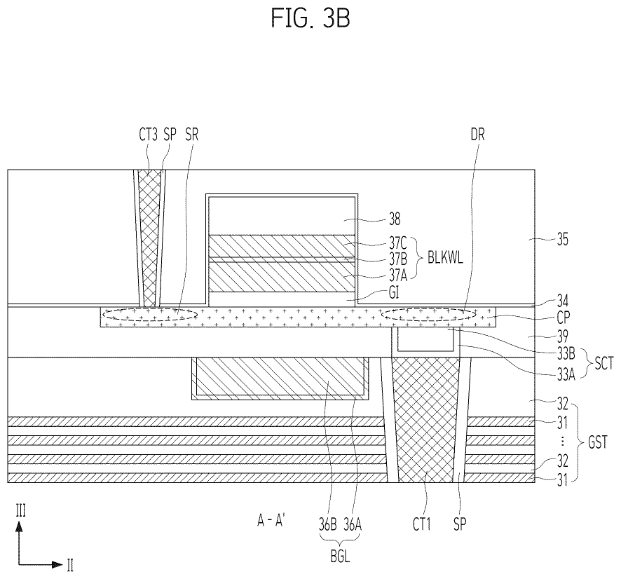

FIGS. 3A and 3B are diagrams illustrating the structure of a semiconductor device in accordance with an embodiment. FIG. 3A is a plan view, and FIG. 3B is a cross-sectional view taken along line A-A′ of FIG. 3A. Hereinafter, the content overlapping with the previously described content may be omitted.

Referring to FIGS. 3A and 3B, the semiconductor device may include a gate structure GST, a channel pattern CP, a back gate line BGL, a block word line BLKWL, a first contact plug CT1, and a second contact plug CT2. The semiconductor device may further include at least one of a gate insulating layer GI, a capping layer 34, an interlayer insulating layer 35, a protective layer 38, an insulating layer 39, insulating spacers SP, a silicide contact plug SCT, a third contact plug CT3, and a fourth contact plug CT4.

The gate structure GST may include conductive layers 31 and insulating layers 32 that are alternately stacked. For example, the conductive layers 31 may be referred to as stacked local lines of which are stacked in a third direction III that intersects the first and second directions I and II as shown in FIG. 3B. In an embodiment, the third direction III may be referred to as a vertical direction or the stacking direction of the conductive layers 31 and the insulating layers 32. The conductive layers 31 may be local lines, and may be source select lines SSL, drain select lines DSL, or word lines WL. The conductive layers 31 may each include a conductive material such as polysilicon, tungsten, or molybdenum. The gate structure GST might not include a staircase structure, and may have an upper surface that is flat.

The first contact plugs CT1 may extend through the gate structure GST, and may be connected to the conductive layers 31, respectively. The first contact plugs CT1 may extend into the gate structure GST at different depths. In an embodiment, the upper surface of the first contact plug CT1 may face the channel pattern CP and away from the stacked conductive layers 31. The insulating spacers SP may surround sidewalls of the first contact plugs CT1, respectively.

The channel patterns CP may be located over the gate structure GST. In an embodiment, the channel patterns CP may, at least partially, vertically overlap with the gate structure GST in the vertical direction. The channel patterns CP may be located to correspond to the first contact plugs CT1, respectively, and may be connected to the first contact plugs CT1, respectively. The channel patterns CP may be located at substantially the same level. Each of the channel patterns CP may include a source region SR and a drain region DR. As an example, the source region SR and the drain region DR may be impurity regions heavily doped with N-type or P-type impurities.

The silicide contact plugs SCT may connect the first contact plugs CT1 and the channel patterns CP to each other, respectively. Each of the silicide contact plugs SCT may include a metal silicide layer 33A and a polysilicon layer 33B. The metal silicide layer 33A may be in contact with the first contact plug CT1, and the polysilicon layer 33B may be located in the metal silicide layer 33A. The polysilicon layer 33B may be in contact with a lower surface of the channel pattern CP. The polysilicon layer 33B may be a polysilicon layer heavily doped with N-type or P-type impurities. The first contact plug CT1 may be connected to the lower surface of the channel pattern CP through the silicide contact plug SCT. Through the silicide contact plug SCT, an ohmic contact may be formed between the first contact plugs CT1 and the channel pattern CP.

The back gate line BGL may be located between the gate structure GST and the channel pattern CP. As an example, the back gate line BGL may be located on the upper surface of the gate structure GST. The back gate line BGL may be located in an uppermost insulating layer 32 of the gate structure GST, and the back gate line BGL and an uppermost conductive layer 31 may be insulated from each other by the uppermost insulating layer 32. An upper surface of the back gate line BGL and an upper surface of the first contact plug CT1 may be coplanar. The back gate line BGL may include a barrier layer 36A and a metal layer 36B located in the barrier layer 36A. In an embodiment, the upper surface of the back gate line BGL may face the channel pattern CP and away from the stacked conductive layers 31.

The block word line BLKWL may be located over the channel patterns CP, and the gate insulating layer GI may be located between the channel patterns CP and the block word line BLKWL. In an embodiment, the channel patterns CP may, at least partially, vertically overlap with the block word line BLKWL in the vertical direction. The block word line BLKWL may include at least one of a first conductive layer 37A, a barrier layer 37B, and a second conductive layer 37C. The second conductive layer 37C may include a material having lower resistivity than the first conductive layer 37A. As an example, the first conductive layer 37A may include polysilicon, and the second conductive layer 37C may include metal such as tungsten or molybdenum. The barrier layer 37B may include metal nitride such as titanium nitride, tantalum nitride, tungsten nitride, or molybdenum nitride.

The block word line BLKWL may extend in parallel with the back gate line BGL, and may extend in a direction intersecting the channel patterns CP. As an example, the block word line BLKWL and the back gate line BGL may extend in a first direction I, and the channel patterns CP may extend in a second direction II intersecting the first direction I.

The protective layer 38 may be located on the block word line BLKWL. In an embodiment, the protective layer 38 may be used to protect the block word line BLKWL in a manufacturing process. As an example, the protective layer 38 may include oxide, and may reduce oxidation of the second conductive layer 37C including tungsten in the manufacturing process.

The capping layer 34 may be formed to surround an upper surface and sidewalls of the block word line BLKWL. In an embodiment, the capping layer 34 may reduce oxidation of the first conductive layer 37A and the second conductive layer 37C exposed through the sidewalls.

The second contact plug CT2 may be connected to the back gate line BGL. A body bias voltage may be applied through the second contact plug CT2 and the back gate line BGL.

The third contact plug CT3 may extend through the interlayer insulating layer 35 and the capping layer 34, and may be connected to the channel pattern CP. The third contact plugs CT3 may connect the channel patterns CP and global lines to each other, respectively. The third contact plugs CT3 may be connected to upper surfaces of the channel patterns CP. In an embodiment, the upper surfaces of the channel patterns CP may face in the direction of the third contact plugs CT3 and away from the gate structure GST. In an embodiment, the lower surfaces of the channel patterns CP may face in the direction of the gate structure GST and away from the third contact plugs CTS.

The fourth contact plug CT4 may extend through the interlayer insulating layer 35, the capping layer 34, and the protective layer 38, and may be connected to the block word line BLKWL. A block select signal may be transmitted through the fourth contact plug CT4 and the block word line BLKWL.

According to an embodiment of the structure described above, pass transistors PT may be located in regions where the block word line BLKWL and the channel patterns CP intersect each other. In an embodiment, the back gate line BGL may be located below the channel patterns CP, and body biases of the pass transistors PT may be controlled by the body bias voltage applied to the back gate line BGL.

In an embodiment, when the back gate line BGL does not exist, a fixed bias might not be applied to the channel pattern CP, and a body region of the channel pattern CP has a floating state. In such a case, in an embodiment, the pass transistor has a three-terminal structure, and a leakage current may occur in the pass transistor. According to an embodiment of the present disclosure, it is possible to implement a pass transistor having a four-terminal structure through the back gate line BGL. In an embodiment, when the body bias voltage is applied to the back gate line BGL, a fixed bias may be applied to the channel pattern CP by coupling. In an embodiment, when a program operation, a read operation, and/or an erase operation is performed, a body bias voltage of about 1.8 V may be applied to the back gate line BGL. Accordingly, in an embodiment, the leakage current of the pass transistor PT may be improved, and a breakdown voltage of the pass transistor PT may be secured.

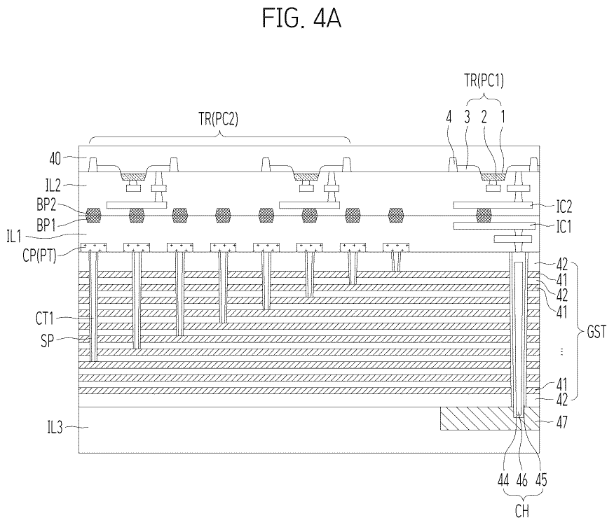

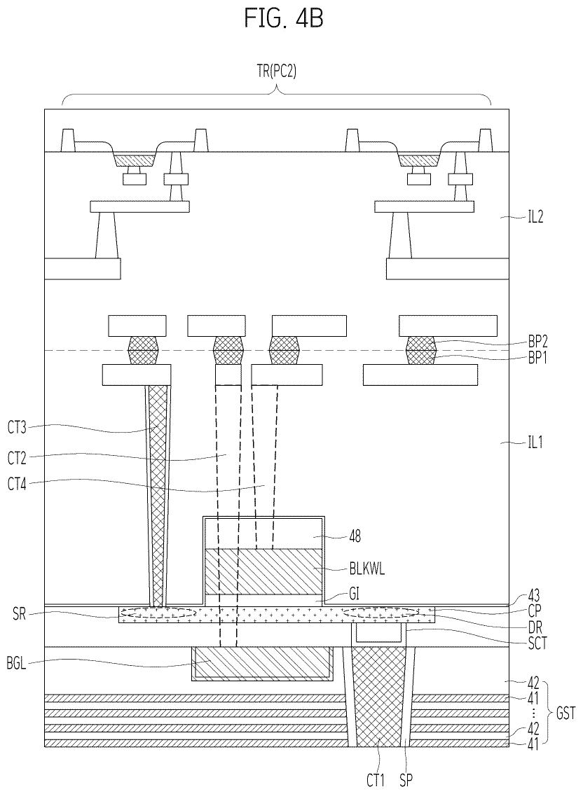

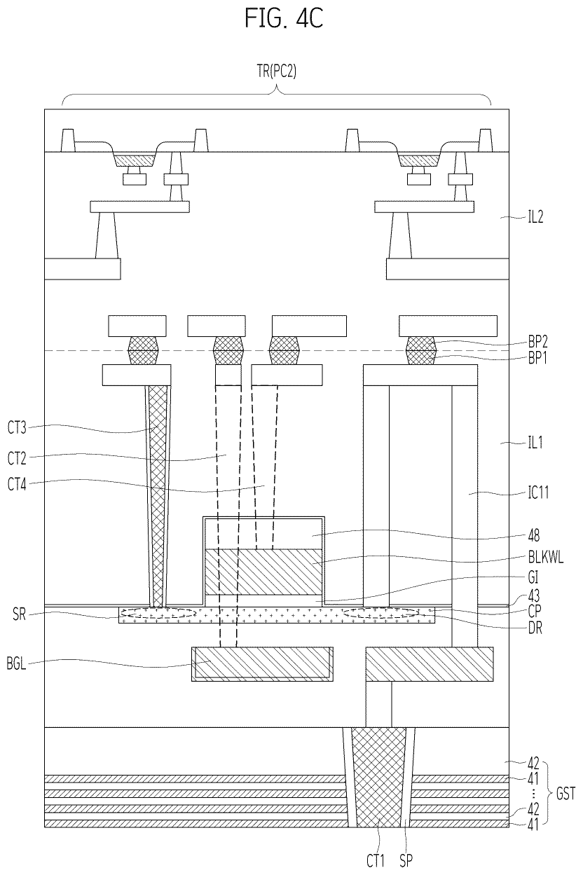

FIGS. 4A to 4C are diagrams illustrating the structure of a semiconductor device in accordance with an embodiment.

Referring to FIGS. 4A and 4B, the semiconductor device may include a gate structure GST, pass transistors PT, a capping layer 43, a protective layer 48, first contact plugs CT1, an insulating spacer SP, a substrate 40, a first peripheral circuit PC1, a second peripheral circuit PC2, a channel structure CH, a source structure 47, a first interlayer insulating layer IL1, a second interlayer insulating layer IL2, a third interlayer insulating layer IL3, a first interconnection structure IC1, a second interconnection structure IC2, a first bonding pad BP1, and a second bonding pad BP2.

The gate structure GST may include conductive layers 41 and insulating layers 42 that are alternately stacked. The first contact plugs CT1 may extend through the gate structure GST, and may be connected to the conductive layers 41, respectively. In an embodiment, the first contact plugs CT1 may be electrically connected to the conductive layers 41, allowing electric signals or current to flow between the first contact plugs CT1 and the conductive layers 41. The insulating spacers SP may surround sidewalls of the first contact plugs CT1, respectively.

The pass transistors PT may be located at and correspond to the first contact plugs CT1, respectively. The pass transistors PT may be located in regions where channel patterns CP and a block word line BLKWL intersect each other. The pass transistor PT may include the channel pattern CP, the block word line BLKWL, a gate insulating layer GI, and a back gate line BGL. The back gate line BGL may be located between the gate structure GST and the channel pattern CP. The first contact plugs CT1 may connect the channel patterns CP and the conductive layers 41 to each other, respectively. A third contact plug CT3 may be connected to a source region SR through an upper surface of the channel pattern CP, and the first contact plug CT1 may be connected to a drain region DR through a lower surface of the channel pattern CP.

The channel structure CH may extend through the gate structure GST. The channel structure CH may include a channel layer 44, a memory layer 45, and an insulating core 46. The source structure 47 may be located under the gate structure GST, and the channel structure CH may extend into the source structure 47. The third interlayer insulating layer IL3 may be located under the source structure 47.

The peripheral circuits PC1 and PC2 may be located on the substrate 40. The peripheral circuits PC1 and PC2 may include a row decoder, a page buffer, a logic circuit, a row decoder-related driver circuit, a data path circuit, a voltage generator, or the like. As an example, an active region may be defined in the substrate 40 by an element isolation layer 4, and a transistor TR may be located in the active region. The transistor TR may include a gate insulating layer 1, a gate electrode 2, and a junction 3.

The first peripheral circuit PC1 may be located over the channel structure CH. The first peripheral circuit PC1 may be connected to the channel structure CH through the first interconnection structure IC1 and the second interconnection structure IC2. As an example, the first peripheral circuit PC1 may include a page buffer. The second peripheral circuit PC2 may be located over the pass transistors PT, and the bonding pads BP1 and BP2 may be located between the pass transistors PT and the second peripheral circuit PC2. In an embodiment, the second peripheral circuit PC2 may vertically overlap with the pass transistors PT in the vertical direction. The second peripheral circuit PC2 may be electrically disconnected from the pass transistors PT. As an example, the second peripheral circuit PC2 may include a row decoder-related driver circuit, a data path circuit, or a voltage generator.

The first interconnection structure IC1 and the first bonding pad BP1 may be located in the first interlayer insulating layer IL1. The first interconnection structure IC1 may include a via, a wiring line, and the like. The first interconnection structure IC1 may be electrically connected to the channel structure CH, the pass transistor PT, and the like. The second interconnection structure IC2 and the second bonding pad BP2 may be located in the second interlayer insulating layer IL2. The second interconnection structure IC2 may include a via, a wiring line, and the like. The second interconnection structure IC2 may be electrically connected to the first and second peripheral circuits PC1 and PC2.

FIG. 4C is a diagram illustrating a modified example of a semiconductor device in accordance with an embodiment. Referring to FIG. 4C, the first contact plug CT1 may be connected to the upper surface of the channel pattern CP through a first interconnection structure IC11. The first interconnection structure IC11 may include a via, a wiring line, and the like. The first contact plug CT1 may be connected to the drain region DR through the upper surface of the channel pattern CP. Other structures may be similar to those of FIG. 4B.

According to an embodiment of the structure described above, a cell array and the peripheral circuit PC may be electrically connected to each other through the first bonding pad BP1 and the second bonding pad BP2. The gate structure GST might not include a staircase structure, and the pass transistors PT may be located on a flat surface of the gate structure GST. In an embodiment, because the pass transistors PT are located on the flat surface of the gate structure GST instead of being located on the substrate 40, an area where the peripheral circuit PC is to be formed on the substrate 40 may be sufficiently secured. In an embodiment, by forming the back gate line between the gate structure GST and the channel pattern CP, it is possible to implement the pass transistor PT having a four-terminal structure.

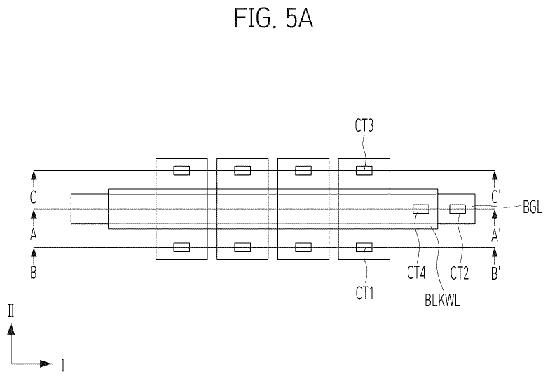

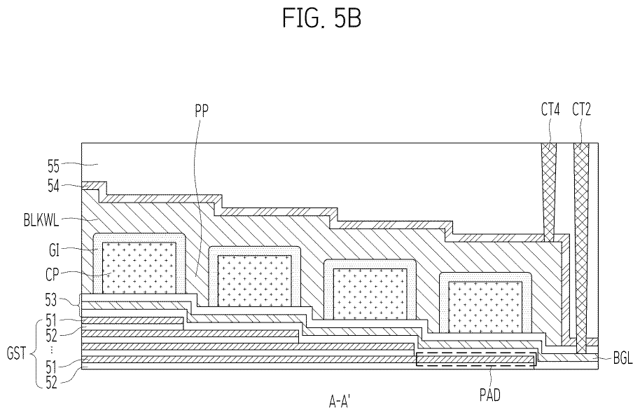

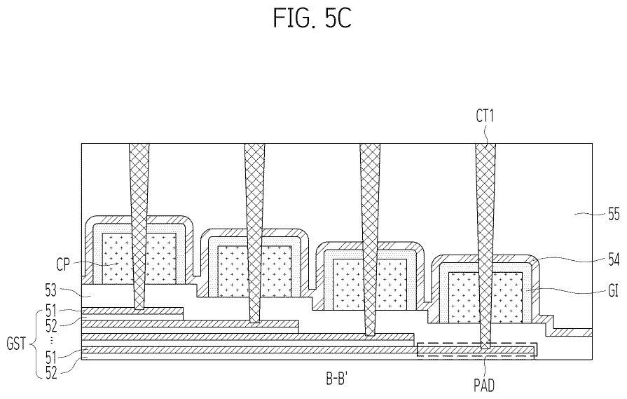

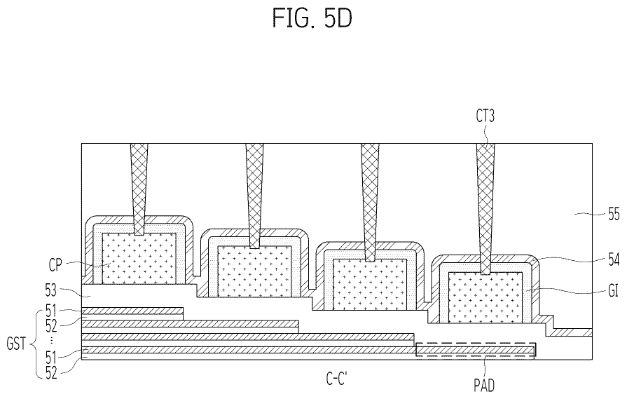

FIGS. 5A to 5D are diagrams illustrating the structure of a semiconductor device in accordance with an embodiment. FIG. 5A is a plan view, FIG. 5B is a cross-sectional view taken along line A-A′ of FIG. 5A, FIG. 5C is a cross-sectional view taken along line B-B′ of FIG. 5A, and FIG. 5D is a cross-sectional view taken along line C-C′ of FIG. 5A. Hereinafter, the content overlapping with the previously described content may be omitted.

Referring to FIGS. 5A to 5D, the semiconductor device may include at least one of a gate structure GST, a channel pattern CP, a buffer layer 53, a gate insulating layer GI, a block word line BLKWL, a back gate line BGL, an etch stop layer 54, an interlayer insulating layer 55, a first contact plug CT1, a second contact plug CT2, a third contact plug CT3, and a fourth contact plug CT4.

The gate structure GST may include conductive layers 51 and insulating layers 52 that are alternately stacked. The conductive layers 51 may be local lines such as a source select line, a drain select line, and word lines. The gate structure GST may include a staircase structure. The staircase structure may extend in the first direction I. Pads PD of the conductive layers 51 may be defined by the staircase structure. Each step of the staircase structure provides a pad, respectively. For example, a portion of the conductive layer 51 that is not covered by upper located conductive layers 51 is defined as a pad PAD.

The buffer layer 53 may be located over the gate structure GST. The buffer layer 53 may be located between the gate structure GST and the channel patterns CP. The buffer layer 53 may be formed along a profile of the staircase structure, and may cover the pads PD. The buffer layer 53 may include an insulating material such as oxide. The back gate line BGL may be located in the buffer layer 53. The back gate line BGL may be located between the gate structure GST and the channel patterns CP, and may extend along the profile of the staircase structure.

The channel patterns CP may be located over the gate structure GST, and may be located over the buffer layer 53. For example, the channel patterns CP may be respectively located over the pads PAD. The channel patterns CP may be arranged to be spaced apart from each other in the first direction I, and may extend in the second direction II. The second direction II may be a direction intersecting the first direction I. As an example, the first direction I and the second direction II may be perpendicular to each other.

The block word line BLKWL may be located over the channel patterns CP, and may extend in the first direction I along the profile of the staircase structure. The gate insulating layers GI may be located between the channel patterns CP and the block word line BLKWL. The gate insulating layers GI may surround the channel patterns CP, respectively. For reference, in an embodiment, it is also possible for the gate insulating layers GI to fill spaces between the channel patterns CP adjacent to each other in the first direction I.

The block word line BLKWL may intersect the channel patterns CP and extend in the first direction I. The etch stop layer 54 may be located on the block word line BLKWL, the gate insulating layer GI, and the buffer layer 53.

The block word line BLKWL may extend in the first direction I while surrounding the channel patterns CP. The block word line BLKWL may surround an upper surface and sidewalls of the channel pattern CP. The block word line BLKWL may extend in the first direction I while surrounding at least three surfaces of the channel pattern CP. For example, the upper surfaces of the channel patterns CP may face towards the etch stop layer 54 and away from the gate structure GST as shown in FIG. 5B. For example, the sidewalls of a channel patten CP may extend between the upper surface of the channel pattern CP and the buffer layer 53 as shown in FIG. 5B. The block word line BLKWL may include protrusion portions PP protruding between the channel patterns CP. Through the protrusion portions PP, in an embodiment, it is possible to increase areas where the block word line BLKWL and the channel patterns CP overlap with each other and improve operation characteristics of a pass transistor PT.

The first contact plugs CT1 may penetrate through the channel patterns CP, and may be connected to the conductive layers 51, respectively. The second contact plug CT2 may be electrically connected to the back gate line BGL. In an embodiment, the second contact plug CT2 may be directly connected to the back gate line BGL. The third contact plugs CT3 may be connected to the channel patterns CP, respectively. The fourth contact plug CT4 may be connected to the block word line BLKWL.

According to an embodiment of the structure described above, the pass transistors PT may be located over the staircase structure of the gate structure GST. In an embodiment, the back gate line BGL may be located below the channel patterns CP, and body biases of the pass transistors PT may be controlled by a body bias voltage applied to the back gate line BGL. Accordingly, in an embodiment, a leakage current of the pass transistor PT may be improved, and a breakdown voltage of the pass transistor PT may be secured.

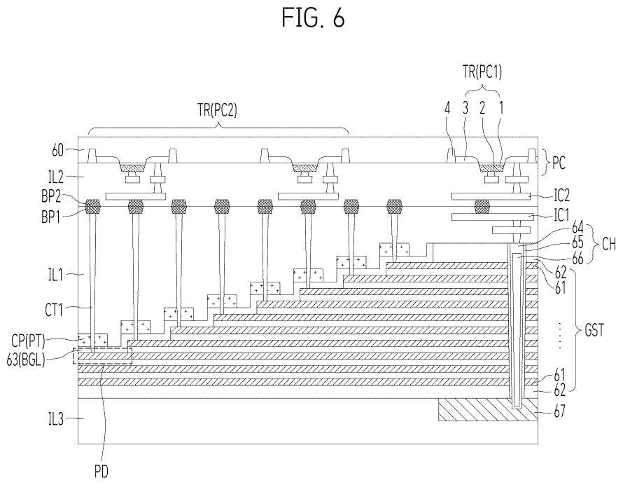

FIG. 6 is a diagram illustrating the structure of a semiconductor device in accordance with an embodiment.

Referring to FIG. 6, the semiconductor device may include a gate structure GST, pass transistors PT, first contact plugs CT1, a substrate 60, a peripheral circuit PC, a channel structure CH, a buffer layer 63, a source structure 67, a first interlayer insulating layer IL1, a second interlayer insulating layer IL2, a third interlayer insulating layer IL3, a first interconnection structure IC1, a second interconnection structure IC2, a first bonding pad BP1, and a second bonding pad BP2. In an embodiment a peripheral circuit PC might include a first peripheral circuit PC1 and a second peripheral circuit PC2.

The gate structure GST may include conductive layers 61 and insulating layers 62 that are alternately stacked. The gate structure GST may include a staircase structure, and each of pads PD of the conductive layers 61 may be defined through the staircase structure. The pass transistors PT may be located over the staircase structure. The pass transistors PT may be located over the pads PD, respectively. The pass transistor PT may include a channel pattern CP, a block word line, a gate insulating layer, and a back gate line BGL.

The buffer layer 63 may be located between the gate structure GST and the channel patterns CP. The back gate line BGL may be located in the buffer layer 63 or between the buffer layer 63 and the gate structure GST. The first contact plugs CT1 may extend through the first interlayer insulating layer IL1, the channel patterns CP, and the buffer layer 63, and may connect the channel patterns CP and the conductive layers 61 to each other, respectively.

The channel structure CH may extend through the gate structure GST. The channel structure CH may include a channel layer 64, a memory layer 65, and an insulating core 66. The source structure 67 may be located over the gate structure GST, and the channel structure CH may extend into the source structure 67. The third interlayer insulating layer IL3 may be located over the source structure 67.

The peripheral circuit PC may be located on the substrate 60. The peripheral circuit PC may include a row decoder, a page buffer, a logic circuit, or the like. As an example, an active region may be defined in the substrate 60 by an element isolation layer 4, and a transistor TR may be located in the active region. The transistor TR may include a gate insulating layer 1, a gate electrode 2, and a junction 3.

The first interconnection structure IC1 and the first bonding pad BP1 may be located in the first interlayer insulating layer IL1. The first interconnection structure IC1 may include a via, a wiring line, and the like. The first interconnection structure IC1 may be electrically connected to the channel structure CH, the pass transistor PT, and the like. The second interconnection structure IC2 and the second bonding pad BP2 may be located in the second interlayer insulating layer IL2. The second interconnection structure IC2 may include a via, a wiring line, and the like. The second interconnection structure IC2 may be electrically connected to the peripheral circuit PC.

According to an embodiment of the structure described above, a cell array and the peripheral circuit PC may be electrically connected to each other through the first bonding pad BP1 and the second bonding pad BP2. In an embodiment, because the pass transistors PT are located over the staircase structure instead of being located on the substrate 60, an area where the peripheral circuit PC is to be formed on the substrate 60 may be sufficiently secured. In an embodiment, by forming the back gate line between the gate structure GST and the channel pattern CP, it is possible to implement the pass transistor PT having a four-terminal structure.

In an embodiment, a case where the gate structure GST includes a reversed staircase structure has been illustrated in FIG. 6, but it is also possible for the gate structure GST to include a forward staircase structure. In addition, in an embodiment, the peripheral circuit PC and the gate structure GST may be sequentially stacked on the substrate, and the bonding pads may be omitted.

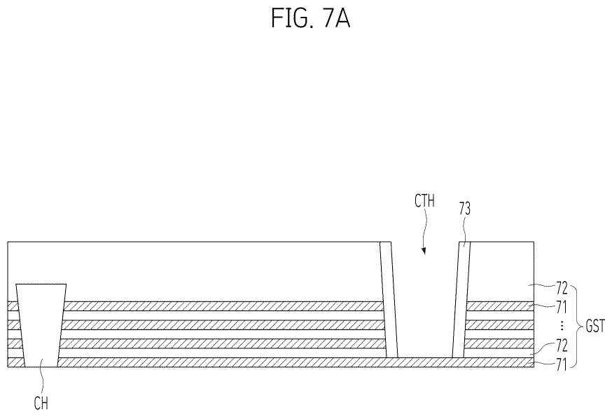

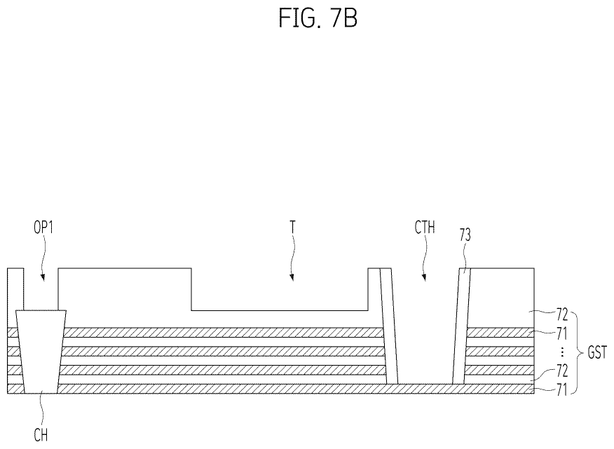

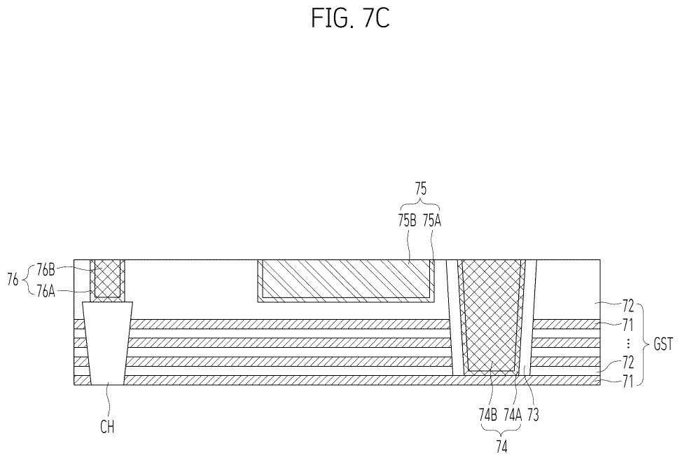

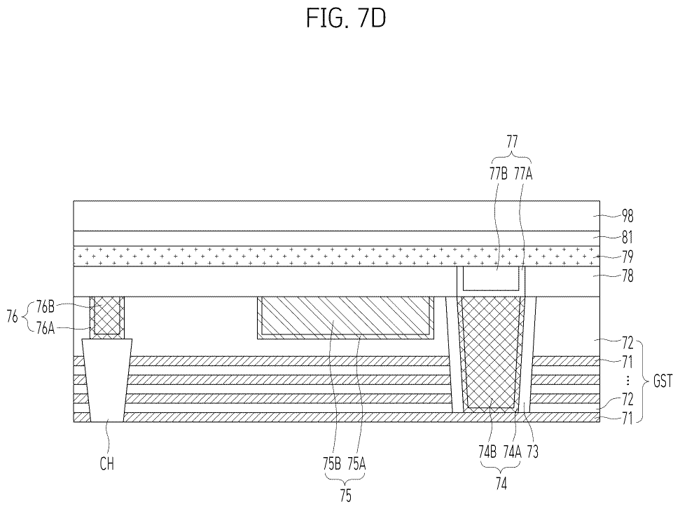

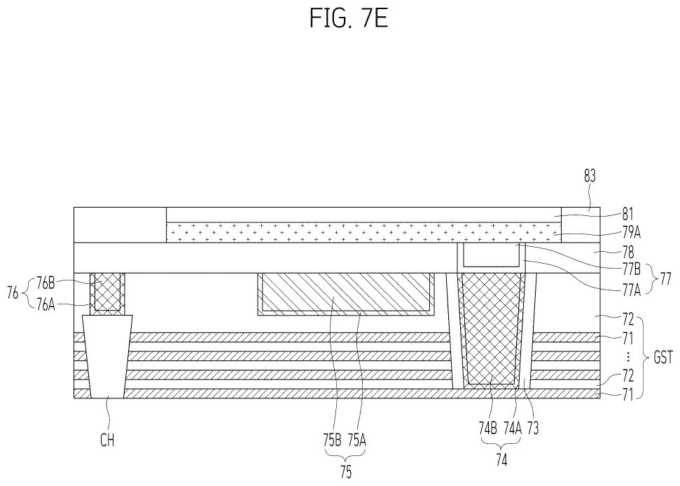

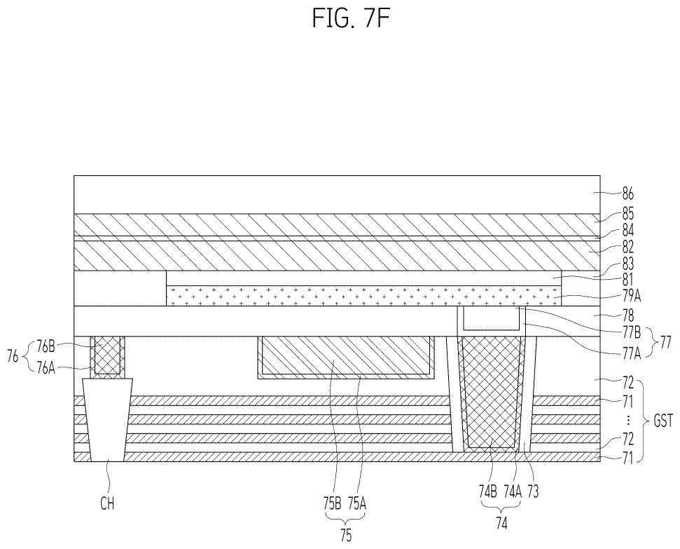

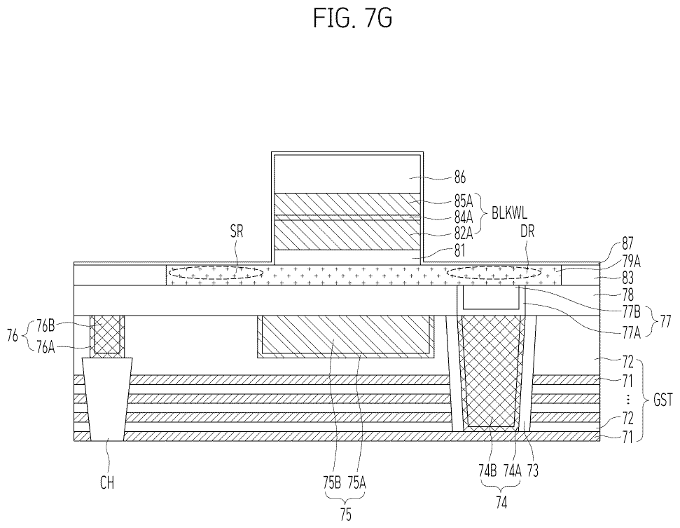

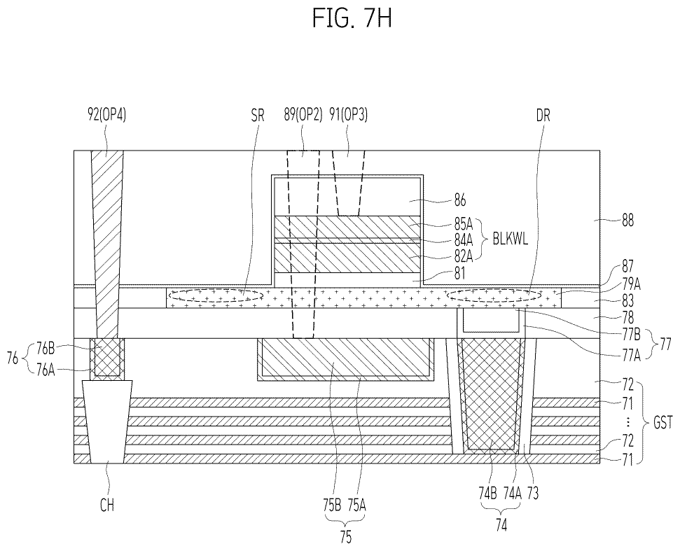

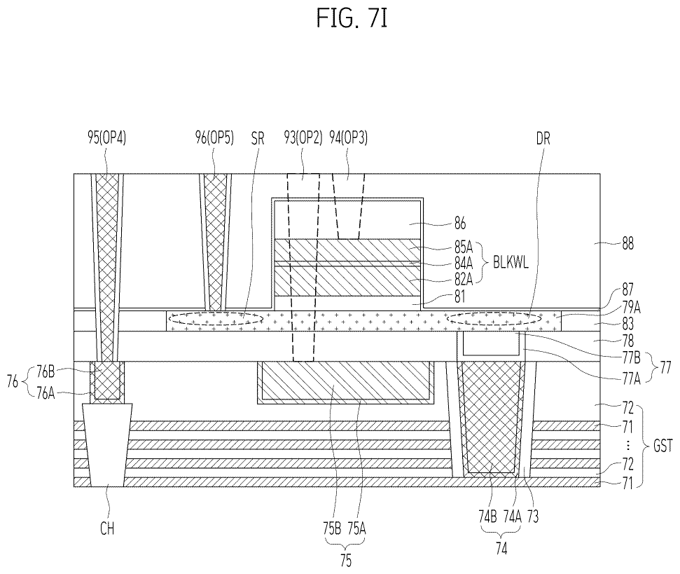

FIGS. 7A to 7I are diagrams for describing a manufacturing method of a semiconductor device in accordance with an embodiment. Hereinafter, the content overlapping with the previously described content may be omitted.

Referring to FIG. 7A, a gate structure GST including conductive layers 71 and insulating layers 72 that are alternately stacked may be formed. A channel structure CH may be located in the gate structure GST. An uppermost insulating layer 72 may have a greater thickness than the remaining insulating layers 72.

Subsequently, a contact hole CTH extending through the gate structure GST and exposing the conductive layer 71 may be formed. As an example, contact holes CTH having different depths and respectively exposing the conductive layers 71 may be formed. Subsequently, insulating spacers 73 may be formed on inner walls of the contact holes CTH.

Referring to FIG. 7B, a trench T and/or a first opening OP1 may be formed in the gate structure GST. As an example, after a sacrificial layer is formed in the contact hole CTH, the trench T and/or the first opening OP1 may be formed. The sacrificial layer may include a spin on carbon (SOC). The trench T and the first opening OP1 may be formed simultaneously or formed by separate processes. The trench T may be located in an upper surface of the gate structure GST, and may be located in the uppermost insulating layer 72. The first opening OP1 may be located in the uppermost insulating layer 72, and may expose the channel structure CH. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Referring to FIG. 7C, a first contact plug 74 may be formed in the contact hole CTH. As an example, a metal layer 74B may be formed after a barrier layer 74A is formed in the contact hole CTH. A back gate line 75 may be formed in the trench T. As an example, a metal layer 75B may be formed after a barrier layer 75A is formed in the trench T. A contact plug 76 may be formed in the first opening OP1. As an example, a metal layer 76B may be formed after a barrier layer 76A is formed in the first opening OP1. The contact plug 76 may be connected to the channel structure CH.

The first contact plug 74, the back gate line 75, and the contact plug 76 may be formed simultaneously or formed by separate processes. As an example, the first contact plug 74, the back gate line 75, and the contact plug 76 may be formed by forming a barrier layer and a metal layer in the contact hole CTH, the trench T, and the first opening OP1 and planarizing the metal layer and the barrier layer until the upper surface of the gate structure GST is exposed. The planarization process may be performed by a chemical mechanical polish (CMP) method.

Referring to FIG. 7D, a silicide contact plug 77 may be formed. As an example, an insulating layer 78 may be formed, and an opening exposing the first contact plug 74 may be formed in the insulating layer 78. Subsequently, a metal layer may be formed in the opening, and a polysilicon layer 77B may be formed in the metal layer. Subsequently, a metal silicide layer 77A may be formed by reacting the metal layer and the polysilicon layer 77B with each other. The metal layer may include titanium, and the metal silicide layer 77A may include titanium silicide (TiSi₂). Through this, the silicide contact plug 77 including the metal silicide layer 77A and the polysilicon layer 77B may be formed.

Subsequently, a channel layer 79 connected to the silicide contact plug 77 may be formed. The channel layer 79 may include a semiconductor material such as silicon germanium (SiGe), polysilicon, or gallium arsenide (GaAs). Subsequently, an impurity injection process for adjusting a threshold voltage of a pass transistor may be performed. As an example, a well region may be formed by doping the channel layer 79 with P-type impurities.

Subsequently, a gate insulating layer 81 may be formed on the channel layer 79. The gate insulating layer 81 may be formed using an oxidation process. Subsequently, an etch stop layer 98 may be formed on the gate insulating layer 81. The etch stop layer 98 may include nitride.

Referring to FIG. 7E, the etch stop layer 98, the gate insulating layer 81, and the channel layer 79 may be etched. Channel patterns 79A extending in the second direction may be formed by etching the channel layer 79. Subsequently, an insulating material may be deposited to fill a region where the gate insulating layer 81 and the channel layer 79 are etched, and an insulating layer 83 may be formed by planarizing the insulating material using the etch stop layer 98.

Referring to FIG. 7F, a first gate layer 82 may be formed on the gate insulating layer 81. As an example, the first gate layer 82 may be formed by depositing a polysilicon layer. The first gate layer 82 may be a polysilicon layer including N-type impurities. Subsequently, a barrier layer 84, a second gate layer 85, and a protective layer 86 may be formed on the first gate layer 82. The barrier layer 84 may include titanium (Ti), tungsten nitride (WN), or tungsten silicon nitride (WSiN). The second gate layer 85 may be a metal layer, and may include tungsten (W). The protective layer 86 may be used to reduce oxidation of the second gate layer 85 in a manufacturing process. As an example, the protective layer 86 may include tetraethyl orthosilicate (TEOS). For reference, it is also possible to form only the first gate layer 82 and omit the barrier layer 84 and the second gate layer 85.

Referring to FIG. 7G, after the protective layer 86 is etched, the second gate layer 85, the barrier layer 84, the first gate layer 82, and the gate insulating layer 81 may be etched. A second gate line 85A extending in the first direction I intersecting the second direction II may be formed by etching the second gate layer 85. A barrier line 84A extending in the first direction I may be formed by etching the barrier layer 84. A first gate line 82A extending in the first direction I may be formed by etching the first gate layer 82. Through this, a block word line BLKWL including the first gate line 82A, the barrier line 84A, and the second gate line 85A may be formed. The block word line BLKWL may include gate lines stacked in multiple layers.

Subsequently, a capping layer 87 may be formed on the block word line BLKWL and the channel pattern 79A. The capping layer 87 may surround sidewalls of the block word line BLKWL. The first gate line 82A, the barrier line 84A, and the second gate line 85A may be exposed through the sidewalls of the block word line BLKWL. The capping layer 87 may reduce oxidation of the exposed first gate line 82A and second gate line 85A. As an example, the capping layer 87 may include nitride.

Subsequently, junctions SR and DR may be formed in the channel pattern 79A. As an example, a source region SR and a drain region DR may be formed by injecting N-type or P-type impurities into the channel pattern 79A through the capping layer 87. The drain region DR may be located close to the silicide contact plug 77.

Referring to FIG. 7H, an interlayer insulating layer 88 may be formed. The interlayer insulating layer 88 may be formed by depositing an insulating material and then planarizing the deposited insulating material. Subsequently, openings OP2, OP3, and OP4 may be formed. In FIG. 7H, for convenience of explanation, the openings OP2, OP3, and OP4 have been illustrated in the same cross section, but the openings OP2, OP3, and OP4 may be located in different cross sections.

A second opening OP2 may extend through the interlayer insulating layer 88, the capping layer 87, the insulating layer 83, and the insulating layer 78, and may expose the back gate line 75. A third opening OP3 may extend through the interlayer insulating layer 88, the capping layer 87, and the protective layer 86, and may expose the second gate line 85A. A fourth opening OP4 may extend through the interlayer insulating layer 88, the capping layer 87, the insulating layer 83, and the insulating layer 78, and may expose the contact plug 76. When the openings OP2, OP3, and OP4 are formed, the metal layers 75B, 85A, and 76B may be used as etch stop layers.

Subsequently, sacrificial layers 89, 91, and 92 may be formed in the openings OP2, OP3, and OP4, respectively. The sacrificial layers 89, 91, and 92 may each include carbon.

Referring to FIG. 7I, a fifth opening OP5 extending through the interlayer insulating layer 88 and the capping layer 87 and exposing the channel pattern 79A may be formed. When the fifth opening OP5 is formed, the channel pattern 79A may be used as an etch stop layer.

For reference, the order of forming the openings OP2, OP3, OP4, and OP5 may be changed depending on materials of the etch stop layers. As an example, the block word line BLKWL may include only the first gate line 82A, and the first gate line 82A may be a polysilicon layer. In such a case, the openings OP2 and OP4 may be formed together using the metal layers 75B and 76B as etch stop layers, and the openings OP3 and OP5 may be formed together using the polysilicon layers 82A and 79A as etch stop layers.

Subsequently, the sacrificial layers 89, 91, and 92 may be removed. Contact plugs 93 to 96 may be formed after insulating spacers 97 are formed in the openings OP2 to OP5. A second contact plug 93 connected to the back gate line 75 may be formed in the second opening OP2. A third contact plug 94 connected to the block word line BLKWL may be formed in the third opening OP3. A fourth contact plug 95 connected to the channel structure CH may be formed in the fourth opening OP4. A fifth contact plug 96 connected to the channel pattern 79A may be formed in the fifth opening OP5. The second to fifth contact plugs 93 to 96 may be formed simultaneously or formed by separate processes.

According to an embodiment of the manufacturing method described above, a pass transistor having a four-terminal structure may be formed over the gate structure GST. The pass transistors may be located in regions where the channel patterns 79A and the block word line BLKWL intersect each other.

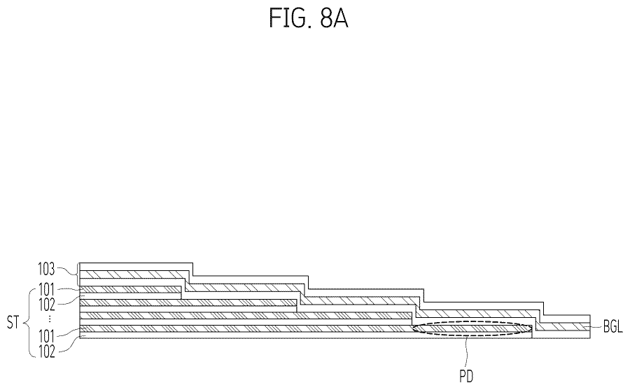

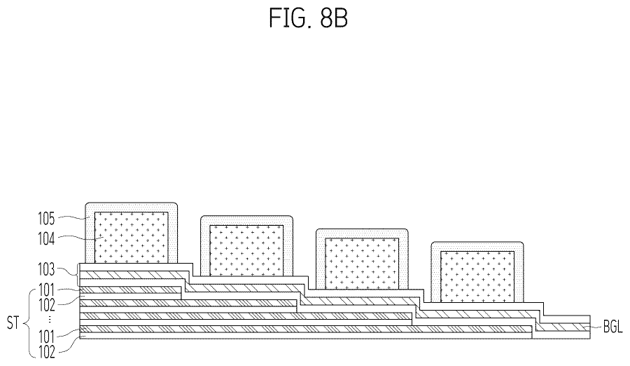

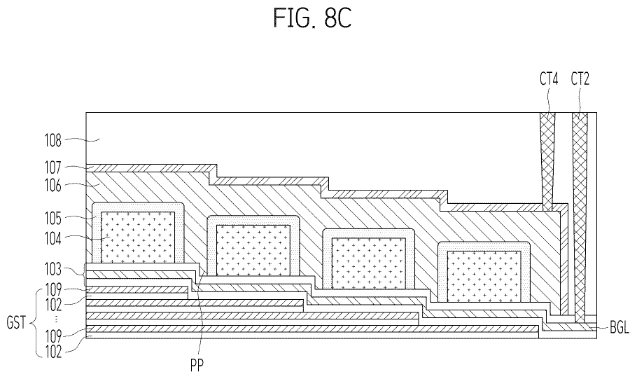

FIGS. 8A to 8C are diagrams for describing a manufacturing method of a semiconductor device in accordance with an embodiment. Hereinafter, the content overlapping with the previously described content may be omitted.

Referring to FIG. 8A, a stack including first material layers 101 and second material layers 102 that are alternately stacked may be formed. Subsequently, a staircase structure may be formed in the stack ST. Each of pads PD of the first material layers 101 may be defined through the staircase structure.

Subsequently, a buffer layer 103 may be formed on the stack ST. The buffer layer 103 may include a back gate line BGL extending along a profile of the staircase structure. As an example, the buffer layer 103 may be formed by forming a first insulating layer on the stack ST, forming the back gate line BGL on the first insulating layer, and forming a second insulating layer on the back gate line BGL. It is also possible to form a trench in the first insulating layer and form the back gate line BGL in the trench.

Referring to FIG. 8B, channel patterns 104 may be formed on the buffer layer 103. As an example, a channel layer may be formed on the buffer layer 103, and may be etched using a mask pattern as an etching barrier. Through this, the channel patterns 104 respectively located on the pads PD may be formed. For example, the channel patterns 104 may be respectively located over the pads PD as shown in FIG. 8B.

Subsequently, gate insulating layers 105 may be formed on the channel patterns 104. As an example, the gate insulating layers 105 may be formed by an oxidation process. Upper surfaces and sidewalls of the channel patterns 104 may be oxidized through the oxidation process, and the gate insulating layers 105 respectively surrounding the channel patterns 104 may be formed. For reference, it is also possible to form the gate insulating layer by a deposition method. In such a case, a space between adjacent channel patterns 104 may be filled with the gate insulating layer.

Referring to FIG. 8C, a block word line 106 may be formed. The block word line 106 may be formed by forming a conductive layer on the gate insulating layers 105 and etching the conductive layer. The block word line 106 may include protrusion portions PP protruding between the channel patterns 104, and may surround the upper surfaces and the sidewalls of the channel patterns 104.

Subsequently, an etch stop layer 107 may be formed on the block word line 106. The etch stop layer 107 is used to adjust a depth of a contact plug formed in a subsequent process, and may include silicon carbon nitride (SiCN).

Subsequently, an interlayer insulating layer 108 may be formed, and the first material layers 101 may be replaced with conductive layers 109. Through this, a gate structure GST including the conductive layers 109 and the second material layers 102 that are alternately stacked may be formed. For reference, when the first material layers 101 each include a conductive material, a replacement process may be omitted. In such a case, the first material layers 101 may be used as the conductive layers, and the stack ST may be used as the gate structure GST.

Subsequently, first contact plugs penetrating through the channel patterns 104 and connecting the channel patterns 104 and the conductive layers 109 to each other, respectively, may be formed. A second contact plug CT2 connected to the back gate line BGL may be formed. Third contact plugs respectively connected to the channel patterns 104 may be formed. A fourth contact plug CT4 connected to the block word line 106 may be formed. When the contact plugs are formed, depths of contact holes may be adjusted using the etch stop layer 107.

According to an embodiment of the manufacturing method described above, a pass transistor having a four-terminal structure may be formed over the gate structure GST. The pass transistors may be located in regions where the channel patterns 104 and the block word line 106 intersect each other.

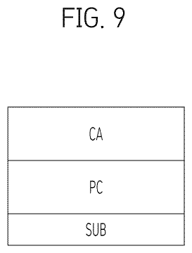

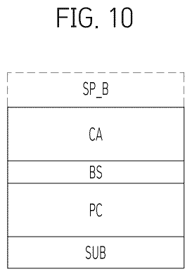

The structures and the manufacturing methods according to the above-described embodiments may be applied to semiconductor devices having various structures. FIGS. 9 and 10 illustrate schematic configurations of semiconductor devices to which the above-described embodiments are applicable.

FIG. 9 is a configuration diagram of a semiconductor device in accordance with an embodiment.

Referring to FIG. 9, the semiconductor device may include a substrate SUB, a peripheral circuit PC, and a memory cell array CA. Here, the peripheral circuit PC and the memory cell array CA may be formed on the same substrate.

The substrate SUB may include a semiconductor material. As an example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. As an example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. As an example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operation voltage, and may include a contact plug, a wiring line, and the like.

The memory cell array CA may include memory cells. As an example, the memory cell array CA may include memory strings connected between a source line and a bit line, and each memory string may include stacked memory cells. As an example, the memory cell array CA may include memory cells connected between a word line and the bit line. The memory cell array CA may further include an interconnection structure.

FIG. 10 is a configuration diagram of a semiconductor device in accordance with an embodiment.

Referring to FIG. 10, the semiconductor device may include a substrate SUB, a peripheral circuit PC, a bonding structure BS, and a memory cell array CA. Here, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. As an example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. As an example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be directly connected to each other without a bonding pad. As an example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring lines, and the like, formed on different wafers may be electrically connected to each other without a separate bonding pad.

Other configurations may be the same as or similar to those described above with reference to FIG. 9.

Meanwhile, it is also possible for the semiconductor device to have a structure in which embodiments described above with reference to FIGS. 9 and 10 are combined with each other or have a partially modified structure. In embodiments described with reference to FIGS. 9 and 10, locations of the memory cell array CA and the peripheral circuit PC may be changed. At least one memory cell array CA and/or at least one peripheral circuit PC may be additionally bonded in an embodiment described with reference to FIG. 9. As an example, a portion of the peripheral circuit PC may be located in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including stacked local lines;
first contact plugs extending through the gate structure and connected to the local lines, respectively;
channel patterns located over the gate structure and connected to the first contact plugs, respectively;
a back gate line located between the gate structure and the channel patterns;
a block word line located over the channel patterns; and
a second contact plug electrically connected to the back gate line.

2. The semiconductor device of claim 1, further comprising silicide contact plugs connecting the first contact plugs and the channel patterns to each other, respectively.

3. The semiconductor device of claim 2, wherein each of the silicide contact plugs comprises:
a metal silicide layer in contact with the first contact plug; and
a polysilicon layer located in the metal silicide layer and in contact with the channel pattern.

4. The semiconductor device of claim 1, wherein an upper surface of the back gate line and upper surfaces of the first contact plugs are coplanar.

5. The semiconductor device of claim 1,
wherein the back gate line and the block word line extend in a first direction, and
wherein the channel patterns extend in a second direction intersecting the first direction.

6. The semiconductor device of claim 1, further comprising:
global lines; and
third contact plugs connecting the channel patterns and the global lines to each other, respectively.

7. The semiconductor device of claim 6,
wherein the first contact plugs are connected to lower surfaces of the channel patterns, and
wherein the third contact plugs are connected to upper surfaces of the channel patterns.

8. The semiconductor device of claim 1, further comprising an interconnection structure connecting the first contact plugs and upper surfaces of the channel patterns to each other.

9. The semiconductor device of claim 1, further comprising a fourth contact plug connected to the block word line.

10. The semiconductor device of claim 1, further comprising:
pass transistors located in regions where the channel patterns and the block word line intersect each other;
a peripheral circuit located over the pass transistors and electrically disconnected from the pass transistors; and
bonding pads located between the pass transistors and the peripheral circuit.

11. A semiconductor device comprising:
a gate structure including stacked local lines, the local lines including pads defined by a staircase structure;
channel patterns located over the pads, respectively;
a block word line located over the channel patterns and extending along a profile of the staircase structure;
a back gate line located between the gate structure and the channel patterns and extending along the profile of the staircase structure;
first contact plugs penetrating through the channel patterns and connecting the channel patterns and the local lines to each other, respectively; and
a second contact plug connected to the back gate line.

12. The semiconductor device of claim 11,
wherein the back gate line and the block word line extend in a first direction, and
wherein the channel patterns extend in a second direction intersecting the first direction.

13. The semiconductor device of claim 11, further comprising:
global lines; and
third contact plugs connecting the channel patterns and the global lines to each other, respectively.

14. The semiconductor device of claim 11, further comprising a fourth contact plug connected to the block word line.

15. The semiconductor device of claim 11, wherein the staircase structure extends in a first direction, and the channel patterns are arranged in the first direction.

16. The semiconductor device of claim 11, further comprising gate insulating layers located between the channel patterns and the block word line.

17. The semiconductor device of claim 11, wherein the block word line includes protrusion portions protruding between the channel patterns.

18. The semiconductor device of claim 17, wherein the block word line surrounds upper surfaces and sidewalls of the channel patterns.
